(19) United States
(12) Patent Application Publication
(10) Pub. No.: US 2025/0279627 A1
(43) Pub. Date: Sep. 4, 2025

(54) VCSEL-BASED ALL-OPTICAL ISING MACHINE

(71) Applicants: NATIONAL UNIVERSITY OF SINGAPORE, Singapore (SG); Agency for Science, Technology and Research, Singapore (SG)

(72) Inventors: Dewen ZHANG, Sinapore (SG); Zifeng YUAN, Singapore (SG); Aaron James DANNER, Singapore (SG); Soon Thor LIM, Connexis North (SG); Thanh Xuan HOANG, Connexis North (SG)

(21) Appl. No.: 19/068,345

(22) Filed: Mar. 3, 2025

(30) Foreign Application Priority Data
Mar. 1, 2024 (SG) 10202400576Y

(51) Int. Cl. H01S 5/065; G02B 27/10; G02B 27/28; G06E 1/00

(52) U.S. Cl. CPC H01S 5/0656; G02B 27/1086; G02B 27/283; G02B 27/286; G06E 1/00; H01S 5/0657

(57) ABSTRACT

An optical, programmable Ising machine uses a master laser for injection locking one or both of the optical frequency and polarization state of slave beams from a plurality of slave lasers—the slave lasers represent Ising bits. The slave beams are split into two or more coupling beams. Some of the coupling beams are rotated (e.g., by) 90°, so that the coupling beams can represent both positive and negative coupling terms between the Ising bits. The coupling beams are then combined and directed back into the optical cavities of the slave lasers, to provided optical feedback, to evolve the state of the Ising machine.

### CROSS-REFERENCE TO RELATED APPLICATIONS

This application claims the benefit and priority of Singaporean patent application number 10202400576Y, filed Mar. 1, 2025. The entire disclosure of the above application is incorporated herein by reference.

### TECHNICAL FIELD

The present invention relates, in general terms, to a programmable, optical Ising machine using a master laser for polarization locking slave lasers representing Ising bits.

### BACKGROUND

This section provides background information related to the present disclosure which is not necessarily prior art.

The reference in this specification to any prior publication (or information derived from it), or to any matter which is known, is not, and should not be taken as an acknowledgment or admission or any form of suggestion that that prior publication (or information derived from it) or known matter forms part of the common general knowledge in the field of endeavour to which this specification relates.

Combinatorial optimization problems are prevalent in many industries, from theoretical mathematics to economics, news propagation, image processing, artificial intelligence and computational biology. The efficient navigation of complex computational spaces has emerged as a fundamental catalyst for progress.

Classical von Neumann computing architectures struggle to provide power-efficient and high-speed solution to such problems. Many of these problems are categorized as non-deterministic polynomial time (NP)-hard or NP-complete. Within the constraints of sequential solving, classical computers face exponential growth in computational time with increased problem complexity.

It would be desirable to provide a mechanism for solving, or approximating the solution to, combinatorial optimization problems.

### SUMMARY

This section provides a general summary of the disclosure, and is not a comprehensive disclosure of its full scope or all of its features.

In response to the above problems, presently proposed is an all-optical Ising machine. Embodiments of the present solution include a fully scalable and programmable parallel optical system with no electrical feedback based on vertical-cavity surface-emitting laser (VCSEL) injection locking for solving Ising problems.

Disclosed is an optical, programmable Ising machine, comprising: a master laser for emitting a diagonally polarized master beam; a plurality of slave lasers each comprising an optical cavity, for emitting a respective slave beam, a polarization state of each slave laser representing a respective Ising bit; a beam modulator for splitting the master beam into a plurality of locking beams and directing each locking beam into the optical cavity of a respective one of the slave lasers, thereby injection locking one or both of an optical frequency and a polarization state of the slave beams; a first optical feedback network (OFN), comprising: a first spatial light modulator (SLM) for splitting each slave beam into two or more coupling beams, the coupling beams comprising a first set of coupling beams and a mutually exclusive second set of coupling beams; a beam rotator for rotating the second set of coupling beams to represent negative coupling terms between the Ising bits, the first set of coupling beams representing a positive coupling term between the Ising bits; and a sequence of further SLMs for directing the coupling beams back to the optical cavities of respective ones of the slave lasers, each coupling beam entering the optical cavity of a different said slave laser to the slave laser that emitted the slave beam corresponding to the respective coupling beam; and a state detector for measuring the polarization state of each slave laser . . .

Advantageously, embodiments of the invention avoid any electrical feedback loop. This all-optical annealing system operates free from energy-consuming and slow-response electrical feedback or refreshment loops. Its exceptional ultrafast processing capability enables the rapid energy-efficient identification of ground states in Ising problems. The present optical Ising machine avoids electrical bottlenecks except, in some embodiments, at the initialization stage where the optical properties of slave lasers are determined, and the readout stage where the solution is read from the Ising machine by reading the state of each slave laser—i.e., the state of light emitted by that laser.

Advantageously, the optical Ising machine is fully programmable. Full programmability involves employing a computer-controlled spatial light modulator (SLM), to afford arbitrary beam shaping, enabling fully programmable injection coupling.

Further areas of applicability will become apparent from the description provided herein. The description and specific examples in this summary are intended for purposes of illustration only and are not intended to limit the scope of the present disclosure.

### BRIEF DESCRIPTION OF THE DRAWINGS

Embodiments of the present invention will now be described, by way of non-limiting example, with reference to the drawings in which:

FIG. 1 schematically illustrates a physical embodiment of an Ising Hamiltonian, in an Ising machine.

FIG. 2 illustrates an embodiment of the laser configuration of an optical Ising machine 200 in accordance with present teachings.

FIG. 3 illustrates an optical Ising machine in accordance with present teachings.

FIG. 4 provides a mechanism for independent manipulation of vertical and horizontal components of slave beams using a polarising beam spitter (PBS).

FIGS. 5a-5d show simulation results depicting the time dynamics of a 16-spin square-lattice injection-locked laser system with a time step of 1×10−14s per iteration. The sections of FIG. 5 illustrate the time evolution of: (section a) Photon numbers in vertical and horizontal polarizations; (section b) computed Ising spins based on the vertical and horizontal polarization photons; (section c) Normalized Ising Hamiltonian; and (section d) 6 sets of spin amplitude patterns representing the Ising spin at 6 different timestamps annotated on sections a to c, where the iterations from i) to vi) are 0, 0.5×104, 1.7×104, 4×104 and 9×104, respectively.

FIG. 6 shows the experimental schematic for VCSEL free-space injection locking.

FIGS. 7a-7b show characterisation of slave VCSELs, with sections a and b showing slave VCSEL polarization bi-stability with increasing bias current at 550C.

FIGS. 8a-8b show characterisation of master VCSELs, with sections a and b showing polarization of master VCSELs across different temperatures and currents.

FIGS. 9a-9b show experimental results on injection locking, with section a showing polarization switching in slave VCSEL with varying injection power from master laser (slave biased at 10 mA, dominant mode: vertical polarization), and section b showing emission spectra comparison among the master VCSEL, the standalone slave VCSEL, and the slave VCSEL during injection locking.

Corresponding reference numerals indicate corresponding parts throughout the several views of the drawings.

### DETAILED DESCRIPTION

Example embodiments will now be described more fully with reference to the accompanying drawings

Operating within a non-von Neumann framework, Ising machines offer high parallelization and efficient handling of NP-hard problems at high speed and with low energy cost. The solution to a combinatorial optimization problem is derived by solving the Ising model, which itself is equivalent to searching for the ground state spin configuration {σ₁, . . . , σ_{N}} corresponding to minimization of the general Ising Hamiltonian:

$$H = {\sum }_{i , j = 1}^{N} {J}_{ij} {σ}_{i} {σ}_{j} + {\sum }_{i = 1}^{N} {λ}_{i} {σ}_{i} \qquad ( 1 )$$

where H represents the Ising Hamiltonian, N is the number of nodes in the model, the terms Jij signify the mutual coupling between nodes i and j, σi and σj denote the spins, each holding values of +1 or −1, and λi is the Zeeman term that accounts for the response of the Ising machine to an external field. In the discussion below, the nodes are equivalent to Ising bits, represented by slave lasers, the spins are the optical properties of slave lasers (e.g., the polarization state or polarization angle) and the Zeeman term is the effect of the master laser beam on the spin of individual nodes.

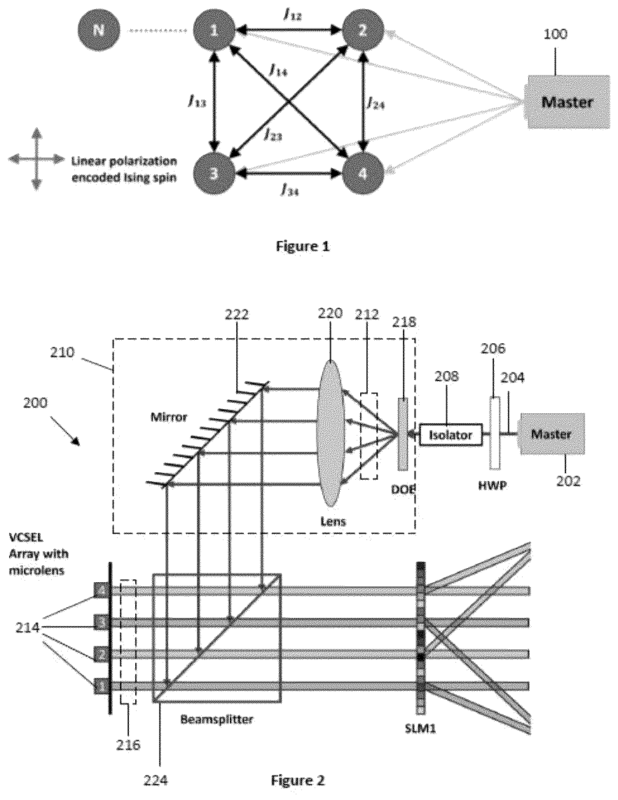

FIG. 1 shows a physical embodiment of the Ising Hamiltonian, using 4 nodes (numbered 1 to 4) each having a spin, and mutual coupling with every other node. In line with present teachings, the nodes are slave lasers that produce light with properties that are considered equivalent to the spins—e.g., two orthogonal polarization states correspond to the two opposite spins. The external field, yielding the Zeeman term, is achieved using the master laser beam generated by the master laser 100.

FIG. 2 illustrates an embodiment of the laser configuration 200 of an optical Ising machine in accordance with present teachings. The laser configuration maps the injection-locked laser system (slave lasers) to the Ising Hamiltonian. The principle of optical injection locking involves synchronizing the oscillation frequency and polarization of a slave laser with external light from a master laser injected into the cavity of the slave laser. In the system of FIG. 2, multiple slave lasers 214 are stabilized by a master laser 202, which is in a stable state of linear polarization. Here, the Ising spins are encoded onto the linear polarization states of individual slave lasers 214, with the number of slaves 214 representing the maximum nodes in the Ising model that the Ising machine set can accommodate.

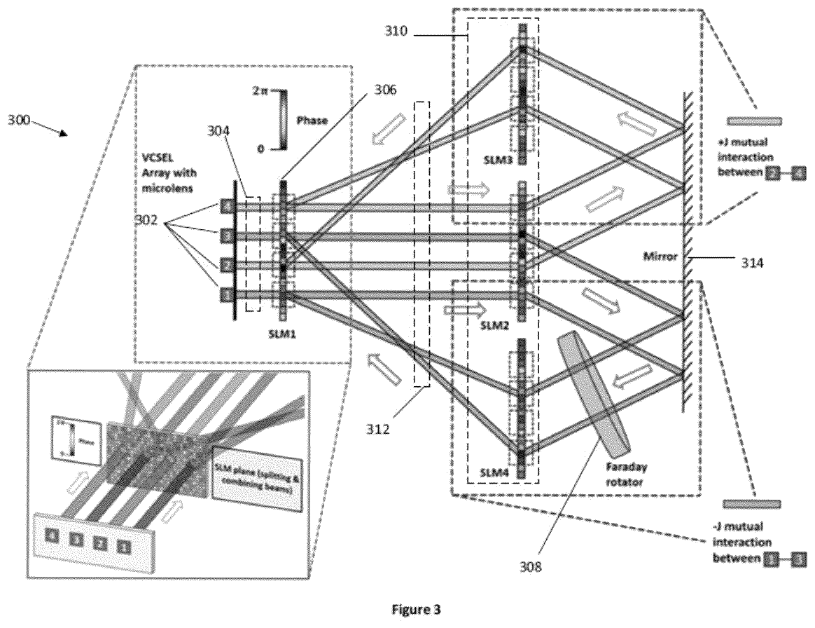

In this setup, the polarization state of a slave laser depends on the external master laser and coupling signals received from other paths among slave lasers, as discussed with reference to the all-optical feedback loop in FIG. 3. The master laser represents the external field Zeeman term, and is initialized in a diagonal polarization state (generally 45o). By injecting a 45° diagonally polarized master beam or light, each slave laser has an equal chance to be at either vertical or horizontal polarization state.

Once initialized, the system naturally anneals toward its lowest energy state, minimizing the Ising Hamiltonian and reaching the optimal spin configuration. VCSELs are promising for implementation as master and slave lasers for these systems due to their scalability and compact size. Arrays of VCSELs can be readily produced with high densities, reaching up to 10,000 per square centimetre, providing a pathway for reasonable scalability in bit representation. The symmetrical beam profile and high-quality cavity factor make them more suitable for injection-locking when compared to edge-emitting lasers, though some embodiments may use edge-emitting lasers or other types of lasers. While single-mode VCSELs typically emit linearly polarized light, the optical Ising machine initialised using the laser configuration 200 requires VCSELs capable of equally favouring one of two orthogonal polarization states to achieve bi-stability. Achieving this isotropic cavity gain demands careful cavity geometry design. Notably, some VCSELs can achieve balanced gain for orthogonally polarized states. Consequently, these VCSELs possess an equal probability of emitting light in either parallel or transverse polarization directions, potentially allowing the system to converge to a single linear polarization state with a minimal injection signal.

Implementing an injection-locked laser network also requires fine-tuning the power splitting ratio, crucially tied to coupling strength—i.e., Jij=Jji but different connections may be stronger than others. The SLMs therefore perform the function or problem, and can be programmed to split a beam into multiple beams and/or control the intensity distribution of individual beams. The magnitude of the coupling strength is mapped to the intensity of light from the slave lasers, where lower intensity refers to smaller magnitude. An Ising problem may comprise various kind of connections. The connectivity between nodes and the weight of individual connection defines the problem.

Two nodes can be connected (mutual influence) or disconnected (no influence). At the same time, the strength of the individual nodes does play a part. The power splitting ratios are fine-tuned to reflect these changes in connection strength. This programmable adjustment enables diverse configurations, essential for solving different Ising problems.

However, the challenge lies in enabling mutual coupling among multiple slave lasers with adjustable attenuation.

In the laser configuration 200, the master laser 202 emits a master beam 204—i.e., beam of light such as a laser beam. In some embodiments, the master laser 202 is configured to directly generate a diagonally polarized master beam. In the embodiment of FIG. 2, the master beam 204 is modulated by a polarizer 206, to ensure the master beam 204 is diagonally polarized. The polarizer 206 is a half wave plate (HWP), though other embodiments may employ a wire grid polarizer, birefringent polarizer or other type of polarizer.

The master beam 204 passes through an isolator 208, that forces the master beam to travel in a single, predetermined direction. Aside from ensuring alignment of the master beam with the beam modulator 210, after modulation by the polarizer 206, the isolator 208 protects the master laser 202 from back reflections and signals generated in the Ising machine.

The master beam 204 passes through a beam modulator 210 that splits the master beam 204 into a plurality of locking beams 212 and directs each locking beam 212 into the optical cavity of a respective one of the slave lasers 214 (numbered 1 to 4). The laser beams are called “locking beams” as they are injected into the optical cavities of slave lasers to locking one or both of an optical frequency and a polarization state of the slave beams 216 generated by the slave lasers 214.

Each slave laser 214 has an optical cavity into which a locking beam 212 is directed. The locking beam 212 injection locks one or both of the optical frequency and polarization state of the optical cavity, such that it generates, on initialization, a beam of the desired frequency or polarization, or both.

The master beam 204 can be diagonally polarized at an angle that causes the optical cavity of each slave laser 214 to exhibit isotropic cavity gain. This results in each optical cavity equally favouring two orthogonal polarization states. In general, this will result in discarding or rejection other polarization states.

The beam modulator 210 includes a diffractive optical element (DOE) 218 and a lens 220 for directing the locking beams to the optical cavities of the slave lasers 214. The DOE 218 splits the master beam 204 into the plurality of locking beams 212. The DOE 218 can split the beam into any desired number of locking beams 212. In some embodiments, the DOE 218 splits the master beam 204 into a 2D (e.g., m×n or m×m) beam matrix of locking beams 212 based on a spatial arrangement of the slave lasers 214. Thus, as the locking beams 212 meet the lens 220, they are spatially arranged with the same spatial arrangement as the slave lasers 214 and are directed in parallel towards those lasers 214. Presently, the locking beams 212 are reflected off a mirror 222, and a beam splitter 224 (acting as a mirror in respect of the locking beams 212), into the optical cavities of the slave lasers 214. This enables the master beam 204 to be injected directly into the optical cavities, while also enabling slave beams 216 to exit the cavities and travel in a direct line towards the first spatial light modulator (SLM) of the Ising machine. As a result, slave beams 216 are easy to align, and few components are needed to facilitate the parallel optical feedback mechanism for converging the Ising machine towards its ground spin state.

FIG. 3 presents an optical, programmable Ising machine 300, omitting the master laser and beam modulator of FIG. 2. For illustration purposes, the optical Ising machine 300 implements an optical parallel feedback system and has four Ising spins, corresponding to the four slave lasers, for simplicity. When read in conjunction with FIG. 1, it is clear that the present teachings can be extended for any number of spins. Polarization locking of a number of slave lasers can be achieved by appropriate selection or configuration of the DOE, or by inserting additional beam splitters between the master laser and slave lasers. This enables the Ising machine 300 to be scaled up to solve problems of arbitrary complexity.

The slave lasers 302 each comprising an optical cavity (not shown), each for emitting a slave beam 304. The polarization state of each slave laser 302 represents an Ising bit of the Ising machine 300. Each slave laser 302 is a vertical-cavity surface-emitting laser (VCSEL).

The slave lasers form a 2D array. Each slave laser 302 has integrated microlenses (or a single collimating lens) to minimise the divergence angle, and thus produce collimated light.

In FIG. 3, all slave beams 304 are emitted towards a first optical feedback network (OFN) that includes a first spatial light modulator (SLM) 306, a beam rotator 308 and a sequence of further SLMs 310.

The SLMs perform various functions including splitting slave beams into coupling beams, combining coupling beams, phase shifting, phase rotation, spatial amplitude and phase. SLMs can be designed to allow arbitrary control of these functions, to achieve a given linear optical function. The SLMs can also be programmed to splits beams, redirect beams and achieve arbitrary desired phase shift in individual parts of the coupling beam or of the coupling beam as a whole—e.g., the SLM can be designed or programmed such that individual pixels (i.e., locations on the SLM to which the coupling beams and slave beam are precisely directed) achieve an arbitrary desired modulation or attenuation. The first SLM 306 (labelled SLM1) splits each slave beam 304 into coupling beams 312. Presently, each slave beam 304 is split into two coupling beams 312, though any other number may be achieved by appropriate configuration of the first SLM 306, in a similar fashion to the DOE 218. The first SLM 306 also redirects each coupling beam 312 to a specific location on a further SLM which will redirect the coupling beam 312 for combining with another coupling beam 312—in this manner, SLM1 programs the interaction terms, Jij. The coupling or interaction term, Jij, presently denotes mutual optical injection between slave lasers with symmetric strengths (Jii=0 and Jij=Jji). In some examples, more than two coupling beams are merged into a single feedback beam directed into the optical cavity of a slave laser. Presently, there are three further SLMs, labelled SLM2, SLM3, and SLM4. SLM2 to SLM4 serve as components to redirect incoming light (coupling beams), coupling it into the appropriate individual slave lasers to achieve optical feedback. A mirror 314 is also used for redirection where light should not pass through, and the angles of incident and reflectance are intended to be the same. Thus, SLM2 to SLM4 direct the coupling beams 312 back to the optical cavities of the slave lasers 302. This involves a series of redirections so that each coupling beam 312 enters the optical cavity of a different slave laser to that which emitted the coupling beam (as part of the slave beam from which the coupling beam was split). Using all-optical feedback, the Ising machine 300 avoids the limitations and slowness of electrical feedback loops.

The SLMs may be programmable liquid crystal on silicon SLMs, segmented mirrors, deformable mirrors or another type of SLM. SLMs can be connected to a computer to facilitate programming of phase modulation, beam splitting and operations on incident beams.

Ising machines achieve convergence on a minimum energy state. Lowering the overall energy of the spins (states of the slave lasers 302) involves injection locking of lasers. All slave beams of FIG. 3 are polarization locked by a common master laser (in some embodiments, there may be multiple master lasers, each set up as shown in FIG. 2, the beams from which are split for different overlapping or non-overlapping sets of slave lasers) using a diagonally polarized locking beam that enables each slave laser to assume an initial one of two states with equal probability. Since there are both positive and negative coupling terms, the beam rotator 308 rotates the phase of a set of coupling beams 312 (presently half the coupling beams 312) to an orthogonal state, to represent negative coupling terms between the Ising bits. This is effectively a manipulation of the polarization states representing +1 and −1 spin states. The beam rotator may incorporate a Faraday rotator or a half-wave plate (HWP) capable of rotating the linear polarization by 90°. This rotation facilitates the switch between vertical and horizontal polarization states. Here, the presence or absence of the beam rotator 308 determines the implementation of the positive or negative coupling term Jij. As a result, SLM2 and SLM3 manage the positive coupling terms (coupling beams that have not been rotated), while SLM3 and SLM4 are responsible for handling the negative coupling terms.

Once the Ising machine 300 iterates to a minimum energy state, a state detector (not shown) measures the polarization state of each slave laser. A state detector (e.g., polarimeter or camera) could be used to measure or read the polarization state of a light beam. Multiple parallel beams could pass through a polarizing beam splitter (PBS) and a camera can be used to look at the beam pattern, where bright and dark beams will provide the polarization information. Alternatively, for multiple beams, each beam may be sequentially read while all other beams are blocked. That polarization state minimises the Ising Hamiltonian, thereby solving the combinatorial optimization problem.

The Ising bits evolve in parallel, each represented continuously by the polarization state of individual VCSELs. The Ising machine 300 operates as follows: initially, a large array of VCSELs (though the present example includes only four VCSELs-slave lasers 302) emits collimated beams. Each VCSEL is designed to favour two orthogonal polarization states over all others, these two states representing the Ising bits ‘1’ and ‘−1’ in the problem to be solved. The SLMs are programmed first, mapping to the specific problem sought to be solved—e.g., by moving the SLMs such that they direct coupling beams towards specific locations on other SLMs to mimic connectivity between nodes. Upon activating the array (e.g., by switching on the master laser and slave laser array, driving the lasers using a laser driver), emitted light in the form of slave beams are split into coupling beams that traverse through the optical feedback network (OFN), mirroring the Ising connectivity graph, represented by Jij. The programmable SLMs 306 and 310 configure light propagation and Ising bit interactions within this network. Notably, the feedback configuration requires a one-time activation only. In this setup, VCSELs 302 receive optical feedback in the form of a beam comprising the combined coupling beams from at least two different slave lasers-notably, in some embodiments, more than two coupling beams may be combined, where the number of coupling beams being combined is directly proportional to the number of coupling beams produced by splitting each slave beam. The feedback influences the polarization states of the VCSELs. Over time, the polarization configuration stabilizes, the final state is recorded, and the Ising problem is solved. This process remains entirely optical, with no optical-electronic information exchange, except for minimal electrical steps during initialization and final state read-out.

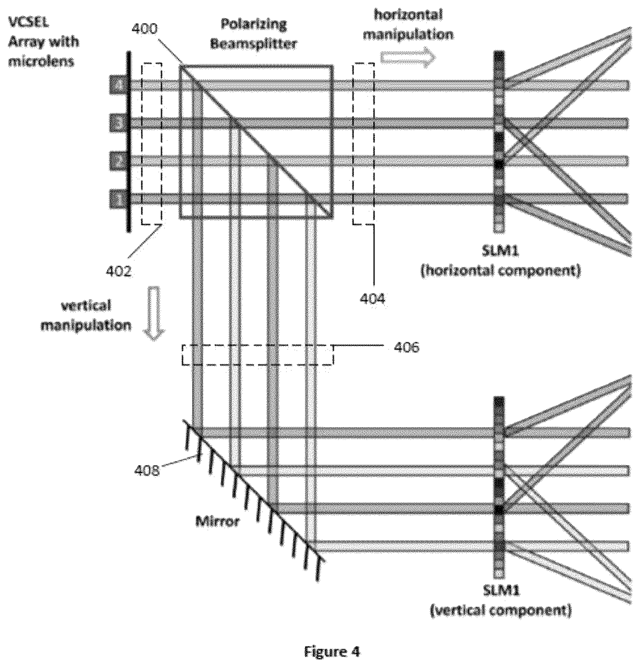

Conventional SLMs face limitations as they rely on incident light aligning precisely with their polarization axis. To tackle this challenge, polarizing beamsplitters can be incorporated into the Ising machine to split light into vertical and horizontal components (beams). In FIG. 4, a polarizing beamsplitter (PBS) 400 is used to separate the slave beams 402 into horizontally and vertically polarized light components 404 and 406, respectively. To maintain parallel beams for processing by OFNs, a mirror 408 reflects the vertical components 406 in parallel towards the second OFN. Each component undergoes independent processing using dedicated SLMs. The spatial manipulation for both components is similar. For example, the horizontal components can be spatially manipulated by the first OFN of FIG. 3, and the vertical components may be spatially manipulated in a common way by a second OFN—i.e., the first and second OFNs spatially manipulate the coupling beams in the same way.

In FIG. 3, SLM1 is programmed to split and redirect the four incident VCSEL beams to specific areas on SLM2, SLM3, and SLM4. These subsequent SLMs are tasked with guiding the incoming light into designated slave laser cavities, forming an injection-locked network. The same functions are achieved by SLMs in the second OFN. This programmable optical parallel feedback system ensures scalability, limited only by the surface area of the SLMs accounting for the number of connections in an Ising graph. Typical Ising problems have many nodes with zero interconnections, yet the SLM configuration can be used to hardware wastage. In addition, the alignment of VCSELs and SLMs in a parallel plane removes the necessity for additional optical alignment and reflecting components. To scale up and create a large-scale photonic Ising machine, expansion involves extending the 2D VCSEL array and accordingly adjusting the SLM plane. Thus, the configuration of FIG. 3 may represent an optimal hardware setup.

### Simulation

The simulation model is derived from the quantum mechanical Langevin equation specific to an injection-locked laser system, facilitating mapping the system to the Ising Hamiltonian. This formulation results in two coupled rate equations, Equations (2) and (3), governing the photon counts (nVi and nHi) within individual slave VCSELs. These equations enable the study of the system's temporal evolution from its initiation at t=0.

Each photon in the system can be vertically polarized (n_{Vi}) or horizontally polarized (n_{Hi}). These states are influenced by factors such as the cavity photon decay rate (ω/Q), spontaneous photon emission due to lasing mode coupling (E_{CVi}), the total amplitude attenuation coefficient (ξ) of the master laser's injection signal (including photon count nm), the amplitude attenuation coefficient (ηᵢ) for the horizontally polarized injection signal from the master laser, mutual injection term's amplitude attenuation coefficient (ξᵢⱼ) between horizontally polarized signals from the slave lasers, and photon number noise (ξₙₒᵢₛₑ).

$$\frac{d}{dt} {n}_{Vi} = - ( \frac{ω}{Q} - {E}_{CVi} ) {n}_{Vi} + {E}_{CVi} + 2 \frac{ω}{Q} \sqrt{{n}_{Vi}} [ ( ζ - {η}_{i} ) \sqrt{{n}_{M}} - {\sum }_{j \neq i} \frac{1}{2} {ξ}_{ij} ( \sqrt{{n}_{Vj}} - \sqrt{{n}_{Hj}} ) ] + {ζ}_{noise} ( {n}_{Vi} ) \qquad ( 2 )$$

$$\frac{d}{dt} {n}_{Hi} = - ( \frac{ω}{Q} - {E}_{CVi} ) {n}_{Hi} + {E}_{CVi} + 2 \frac{ω}{Q} \sqrt{{n}_{Hi}} [ ( ζ - {η}_{i} ) \sqrt{{n}_{M}} - {\sum }_{j \neq i} \frac{1}{2} {ξ}_{ij} ( \sqrt{{n}_{Vj}} - \sqrt{{n}_{Hj} j} ) ] + {ζ}_{noise} ( {n}_{Hi} ) \qquad ( 3 )$$

Consider the situation at t=0, the moment that the system of lasers is just being switched on,

$$\frac{d}{dx} {n}_{Vi} = \frac{d}{dx} {n}_{Hi} = 0 ,$$

and the rate of change of charge carriers is also 0. The spontaneous photon emission due to lasing mode coupling E_{CVi} for the sum of Equations (2) and (3) can be found as follows:

$${E}_{CVi} = \frac{ω}{Q} - 2 \frac{ω}{Q} ζ \frac{\sqrt{{n}_{M}} ( \sqrt{{n}_{Vi}} + \sqrt{{n}_{Hi}}}{{n}_{Vi} + {n}_{Hi}} + 2 \frac{ω}{Q} \frac{\sqrt{{n}_{Vi}} - \sqrt{{n}_{Hi}}}{\sqrt{{n}_{Vi} + {n}_{Hi}}} [ {η}_{i} \frac{\sqrt{{n}_{M}}}{\sqrt{{n}_{Vi} + {n}_{Hi}}} + {\sum }_{j \neq i} \frac{1}{2} {ξ}_{ij} \frac{\sqrt{{n}_{Vi}} - \sqrt{{n}_{Hi}}}{\sqrt{{n}_{Vi} + {n}_{Hi}}} ] \qquad ( 4 )$$

Upon iteration, the expectation is that the coherently coupled slave laser systems oscillates with a polarization configuration that minimizes the overall loss. The first and second terms of the right-hand side of Equation (4) are almost independent of the polarization configurations, so that the spontaneously selected single-lasing mode polarization state in the entire system is expected to be minimized. This gives the following expression:

$${\sum }_{i} \frac{\sqrt{{n}_{Vi}} - \sqrt{{n}_{Hi}}}{\sqrt{{n}_{Ti}}} [ {η}_{i} \frac{\sqrt{{n}_{M}}}{\sqrt{{n}_{Ti}}} + {\sum }_{j \neq i} \frac{1}{2} {ξ}_{ij} \frac{\sqrt{{n}_{Vi}} - \sqrt{{n}_{Hi}}}{\sqrt{{n}_{Ti}}} ]$$

The optical parallel feedback system has the advantage of being scalable, potentially enabling on-chip large-scale photonics Ising computing. In large-scale photonics systems, photon number noise is unavoidable and can accumulate to levels that disrupt the stability of optical machines. Quantum noise sources can be introduced, modifying the Zeeman term, to disrupt convergence towards local minima in favour of reaching the global minimum, thereby enhancing the chances of finding the ground state of the Ising Hamiltonian. Conversely, excessive noise may detrimentally affect optical computing machines. To better simulate the actual physical system of an injection locking laser network, an additional Gaussian noise term ξnoise (nVi) is added to Equations (2) and (3), with a mean value of 0 and standard deviation \sqrt{n_{Vi}}.

$${σ}_{i} = \frac{\sqrt{{n}_{Vi}} - \sqrt{{n}_{Hi}}}{\sqrt{{n}_{Ti}}} where {n}_{Ti} = {n}_{Vi} + {n}_{Hi} \qquad ( 4 )$$

The effective Ising spin is defined as

$${σ}_{i} = \frac{\sqrt{{n}_{Vi}} - \sqrt{{n}_{Hi}}}{\sqrt{{n}_{Ti}}}$$

where −1≤σᵢ≤1, and interpreting

$${η}_{i} \frac{\sqrt{{n}_{M}}}{\sqrt{{n}_{Ti}}}$$

as the Zeeman term, ξᵢⱼ as Ising interaction term Jᵢⱼ, the final equation becomes:

$${\sum }_{i} {η}_{i} \frac{\sqrt{{n}_{M}}}{\sqrt{{n}_{Ti}}} {σ}_{i} + {\sum }_{j \neq i} {ξ}_{ij} {σ}_{i} σ j \qquad ( 5 )$$

where

$${η}_{i} = α \frac{{λ}_{i}}{max [ \vert {J}_{ij} \vert , \vert {λ}_{i} \vert ]} and {ξ}_{ij} = {α}^{′} \frac{{J}_{ij}}{max [ \vert {J}_{ij} \vert , \vert {λ}_{i} \vert ]} .$$

Thus, the Ising spin states are determined according to Equation (4), where σᵢ falls within the range of −1 to 1. Equation (4) is used to visualize the annealing process in simulation, showcasing intermediate Ising states. However, in a physical implementation, where σᵢ assumes values of −1 or 1, spin is assigned values using a majority vote principle: σᵢ=1 if n_{Vi}>n_{Hi} and σᵢ=−1 if n_{Vi}<n_{Hi}. This method allows for the assignment of spin values based on the prevailing photon counts between vertical and horizontal polarizations.

To demonstrate the capability of the proposed injection locking laser system as a general solver for optimization problems, a machine set up based on the schematic shown in FIGS. 2 to 4 was used to simulate 4-bit and 16-bit MAXCUT problems. The MAXCUT problem is an NP-hard problem, involving partitioning a graph Jij into two subsets such that the number of edges between these two subsets is maximized. MAXCUT problems can be easily converted to an Ising model using the graph structure Jij and assigning each non-zero edge as antiferromagnetic (Jᵢⱼ=−1). The minimum energy state of the Ising Hamiltonian corresponds to the maximum cut solution to the problem.

The square-lattice structure and all-to-all connectivity structure have been analyzed. For the square-lattice structure, the spins are organized in a two-dimensional (2D) grid and interact with their four nearest neighbours. The solution for a square-lattice setup is a checkerboard pattern, with alternating σᵢ=1 and σᵢ=−1 configurations among neighbouring spins. In the discussion below, the focus in mainly on the 16-bit square-lattice structure, since the detailed analysis for the 4-bit follows similar reasoning.

A 4×4 (16-bit) square lattice with periodic boundary conditions was implemented. FIG. 5 presents simulation results obtained from the coupled rate equations. Initially, all the slave lasers are vertically polarized, with the photon counts set at n_{Vi}=10×10 and n_{Hi}=0. The spin states are initialized as +1, influenced by the master laser's locking. Thus, at timestamp i) 16 spins with almost identical colour can be observed, the small difference in the colour gradient was due to the Gaussian noise term ξₙₒᵢₛₑ (n_{Vi}) added into the system. In the early stages following initialization, a complex temporal evolution of photon numbers occurred, along with bifurcation of the spin states within the mutually injected slave VCSELs. This can also be seen in section d from timestamp i) to iii), where the Ising spin amplitude begins to evolve to search for its ground state. At timestamp iv) (1.7×10⁴ iterations), the Hamiltonian is near the ground state, where majority of the spins are already organized in a checkerboard pattern except for one bit having spin amplitude around −0.6. Over time, the photon numbers stabilize, and the spin states reach steady configurations.

This convergence reveals an outcome where half of the lasers become horizontally polarized while the remaining half remain vertically polarized. The target alternating checkerboard pattern was observed. This outcome accurately predicts the solution for the MAXCUT problem.

### Injection Locking Experiments

Experiments were conducted to validate the feasibility of the present implementation of an injection locking laser system, employing a master VCSEL and a slave VCSEL. This aimed to demonstrate orthogonal injection locking by injecting an optical signal with linear polarization perpendicular to the dominant polarization of the slave VCSEL. The slave VCSELs exhibited polarization bi-stability across various bias currents. Operating with two polarization modes along orthogonal crystal axes, these VCSELs display bistable behaviour. At specific bias currents, the anisotropic gain within their cavities determines the dominance of either the parallel or orthogonal mode, suppressing the other mode.

The effectiveness of injection locking as proposed herein, relies on several crucial factors: coupling coefficients, injection power efficiency, and wavelength detuning. Optimal performance demands strong coupling, highly efficient injection power, and minimal wavelength detuning to ensure stable polarization switching under injection lock conditions. Within the present optical parallel feedback architecture—where light from each VCSEL interacts with other VCSEL cavities—the determination of the minimum power required for stable injection locking is important.

For optical computing systems to compete with classical computers, it requires scaling to handle millions of bits. In the present system, arrays of at least 1000×1000 VCSELs would be suitable to surpass classical computers in specific computing applications. The success of large-scale photonic Ising machines hinges on achieving stable injection locking with minimal power consumption. Therefore, the injection locking experiments aim to achieve stable injection locking with minimal power, highlighting the importance of precise spatial alignments and minimal wavelength detuning as primary conditions.

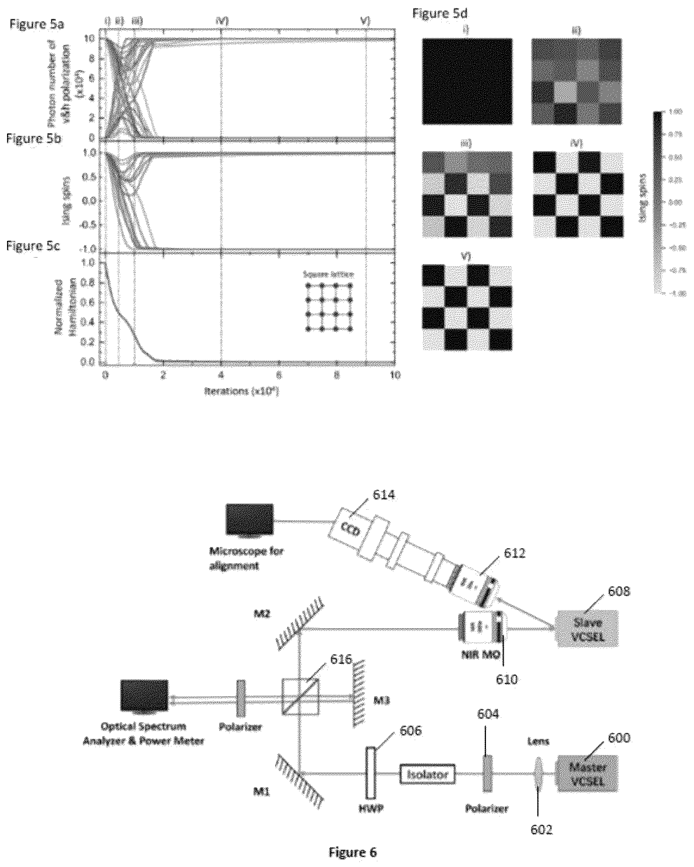

The experimental setup, depicted in FIG. 6, begins with collimated light from the master VCSEL 600, focused through a lens 602. The injected power is modulated by rotating the polarizer 604, while precise polarization adjustment relies on both the polarizer 604 and the half-wave plate (HWP) 606 to ensure the polarization of injected light is orthogonal to that of the slave VCSEL 608. Achieving accurate focusing onto the slave VCSEL optical cavity is facilitated by the 100× near-infrared microscope objective (NIR MO) lens 610.

Additionally, the 20× NIR MO 612, equipped with a CCD camera 614, is used for precise adjustment of the injected beam and the slave cavity. For signal measurements, a non-polarizing beam splitter (BS) 616 and mirror M3 were used to detect the light from the master VCSEL 600. Removing the mirror M3 allows detection of the lasing signal from the slave VCSEL 608.

VCSELs can exhibit polarization bi-stability through varying bias current and temperature. Through careful manipulation of these parameters, isotropic cavity gain can be achieved which equally favours both orthogonal polarization states. When VCSELs are biased at the polarization switching region, polarization mode hopping will take place, and VCSELs can easily/unpredictably switch between the two well-defined orthogonal linear polarization states. Consequently, these VCSELs can nominally have a 50-50 chance of emitting light in either polarization direction when slowly switched on.

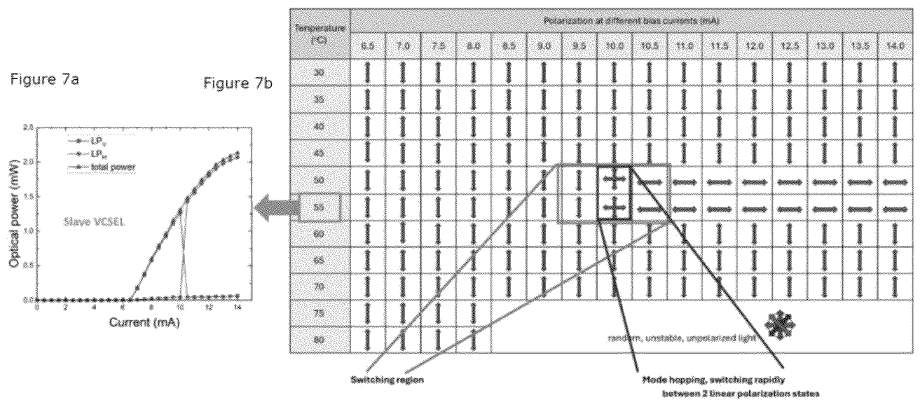

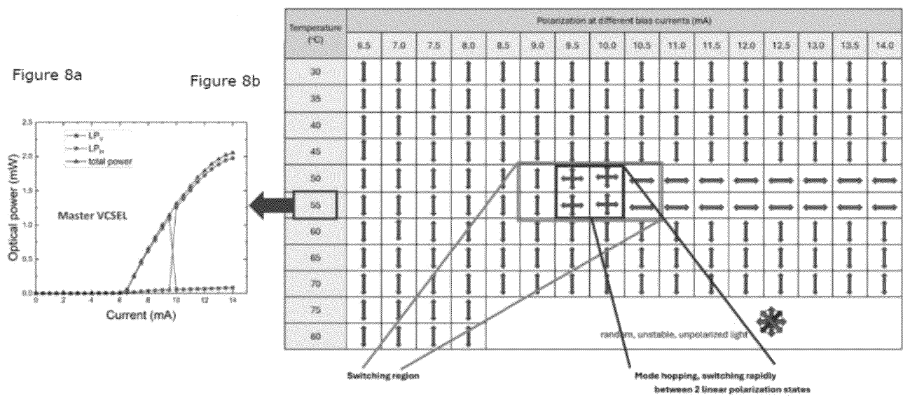

The polarization bi-stability of both slave and master VCSELs, operating at a wavelength of 840 nm, was initially characterized by incrementally increasing the bias current from 0 mA to 14 mA while maintaining different temperatures with a temperature controller. The polarization dynamics of slave VCSELs are summarized in FIG. 7, sections a and b, and of master MCSELs in FIG. 8, sections a and b. Both the slave and master VCSELs demonstrate nearly identical polarization characteristics. When operated at a bias current of 10 mA and maintained at a temperature of 55° C., the VCSELs became suitable Ising bits, exhibiting 50:50 polarization bi-stability. The only difference is that the master VCSEL switches at 9.5 mA and has a marginally larger switching region.

In FIG. 8, sections a and b, the VCSEL's optical power of vertical and horizontal linear polarizations (LPV & LPH) are plotted against bias current. The threshold current is identified as 6.5 mA. Beyond this threshold, the VCSEL predominantly emits light in a vertically polarized mode. However, a notable shift occurs at 10.5 mA for the slave VCSEL and at 10 mA for the master VCSEL, where the dominant mode abruptly switches to the (orthogonal) horizontal polarization. This shift arises due to a change in the gain curve of the previously suppressed mode compared to the dominant mode as bias current increases.

The slave laser was biased at 10 mA and the temperature was held constant at 55° C. In order to achieve injection locking, the spectra of the slave and master laser need to be aligned. Spectra of the master laser biased at 12 mA over a temperature ranging from 10° C. to 60° C. was characterized. The master laser is biased at 12 mA, 50° C., with a centre wavelength around 840.6 nm to match the slave VCSEL wavelength over the bi-stability range (10 mA, 55° C.). It is important to note that the master VCSEL is biased at the stable emission region with horizontally polarized light to provide a stable optical signal for injection locking.

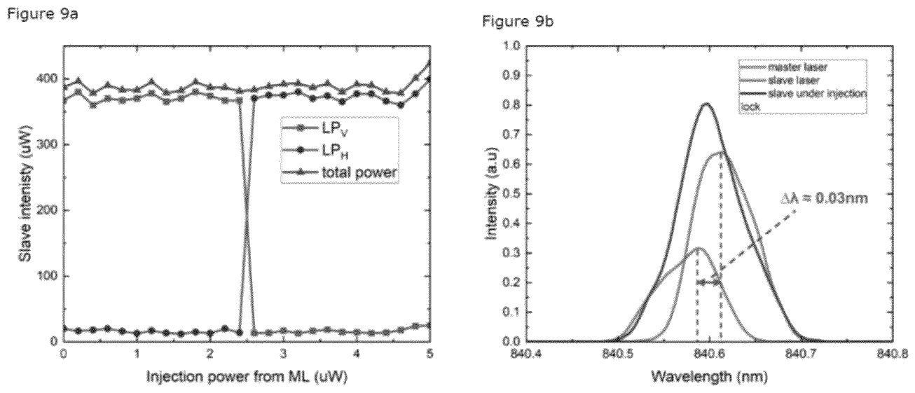

In FIG. 9, section b, the optical spectrum of both the master and slave VCSELs illustrates a minimal wavelength detuning of 0.03 nm. Maintaining the slave VCSEL parameters, the optical power output measured from the slave laser was found to be 1.26 mW. Dependence of the optical power of the two polarization modes on the injection power from the master laser was shown in FIG. 9, section a. Remarkably, under good spatial alignment and minimal wavelength detuning, less than 1% of the master laser's power was necessary to induce a stable polarization switch. Specifically, the polarization switching occurs at a mere 2.5 μW of injected power, significantly lower than the 1260 μW optical emission from the slave VCSEL. Successful injection locking of the slave VCSEL by the master VCSEL was confirmed by a spectrum shift towards the injected signal.

The experimental results showcase the successful injection locking with remarkably low injection power, facilitated by precise spectral and spatial alignments. The observed polarization switching using less than 1% of injected light underscores the scalability and viability of the proposed optical parallel feedback system as a functional photonic Ising machine. The fan-out problem—wherein one VCSEL needs to couple with many while others connect to few—can potentially be mitigated through unequal current injection strategies.

As demonstrated by simulation and experiment, the present teachings result in an all-optical scalable and programmable parallel feedback system, employing mutual injection locking of VCSELs and SLMs. Such a system aims to remove electrical bottlenecks to achieve all-optical computation and to avoid any hardware wastage through spatially programmable SLMs. Leveraging VCSELs for scalability and compactness provides a pathway for large-scale all-optical Ising machines. This was successfully demonstrated for solving up to 16-bit square-lattice and all-to-all connection MAXCUT optimization problems. The system is able to anneal to its ground state and achieve an accurate solution for the given problem in a short time. Moreover, experiments demonstrate that even a small injection power can induce a polarization change in the slave VCSEL beam, allowing for injection locking of up to 100 bits using current SLMs and laser systems.

It will be appreciated that many further modifications and permutations of various aspects of the described embodiments are possible. Accordingly, the described aspects are intended to embrace all such alterations, modifications, and variations that fall within the spirit and scope of the appended claims.

Throughout this specification and the claims which follow, unless the context requires otherwise, the word “comprise”, and variations such as “comprises” and “comprising”, will be understood to imply the inclusion of a stated integer or step or group of integers or steps but not the exclusion of any other integer or step or group of integers or steps.

What is claimed:

1. An optical, programmable Ising machine, comprising:
a master laser for emitting a diagonally polarized master beam;
a plurality of slave lasers each comprising an optical cavity, for emitting a respective slave beam, a polarization state of each slave laser representing a respective Ising bit;
a beam modulator for splitting the master beam into a plurality of locking beams and directing each locking beam into the optical cavity of a respective one of the slave lasers, thereby injection locking one or both of an optical frequency and a polarization state of the slave beams;
a first optical feedback network (OFN), comprising:
a first spatial light modulator (SLM) for splitting each slave beam into two or more coupling beams, the coupling beams comprising a first set of coupling beams and a mutually exclusive second set of coupling beams;
a beam rotator for rotating the second set of coupling beams to represent negative coupling terms between the Ising bits, the first set of coupling beams representing a positive coupling term between the Ising bits; and
a sequence of further SLMs for directing the coupling beams back to the optical cavities of respective ones of the slave lasers, each coupling beam entering the optical cavity of a different said slave laser to the slave laser that emitted the slave beam corresponding to the respective coupling beam; and
a state detector for measuring the polarization state of each slave laser.

2. The optical, programmable Ising machine of claim 1, comprising a polarizing member between the master laser and beam modulator, for diagonally polarizing the master beam.

3. The optical, programmable Ising machine of claim 2, wherein the polarizing member is a half-wave plate (HWP).

4. The optical, programmable Ising machine of claim 1, wherein the master beam is diagonally polarized at an angle that causes the optical cavity of each slave laser to exhibit isotropic cavity gain, resulting in each optical cavity equally favouring two orthogonal polarization states.

5. The optical, programmable Ising machine of claim 1, wherein the beam modulator comprises a diffractive optical element (DOE) for splitting the master beam into the plurality of locking beams, and a lens for directing the locking beams to the optical cavities of the slave lasers.

6. The optical, programmable Ising machine of claim 5, wherein the DOE splits the master beam into a 2D matrix of said locking beams based on a spatial arrangement of the slave lasers.

7. The optical, programmable Ising machine of claim 1, comprising:
a polarizing beam splitter for splitting each slave beam into a horizontally polarized component and a vertically polarized component, wherein the horizontally polarized components are spatially manipulated by the first OFN; and
a second OFN for spatially manipulating the vertically polarized components in a common way to spatial manipulating of the horizontally polarized components by the first OFN.

8. The optical, programmable Ising machine of claim 1, wherein each laser is a vertical-cavity surface-emitting laser (VCSEL).

9. The optical, programmable Ising machine of claim 1, wherein the master laser is initially set to a 45° diagonal polarization.

10. The optical, programmable Ising machine of claim 1, wherein each locking beam passes through one said further SLM, exiting at an angle to direct the locking beam at a specific location on a second said further SLM.

11. The optical, programmable Ising machine of claim 1, wherein the beam rotator is one of a Faraday rotator and a half wave plate.

12. The optical, programmable Ising machine of claim 1, wherein each slave laser comprises a lens for reducing a divergence angle of the respective slave beam.

13. The optical, programmable Ising machine of claim 1, wherein the sequence of further SLMs direct the coupling beams back to the optical cavities through the first SLM, the first SLM combining coupling beams received from the further SLMs and directing the combined coupling beams back to the optical cavities.

14. The optical, programmable Ising machine of claim 1, wherein one or more of the first SLM and further SLMs are configured to manipulate the slave beam or coupling beams in a predetermined way.

15. The optical, programmable Ising machine of claim 1, wherein each OFN comprises a mirror for reflecting coupling beams passing through each further SLM to a different further SLM.

16. The optical, programmable Ising machine of claim 1, wherein the first SLM directs the combined coupling beams into the optical cavities in parallel.
